(19) United States
(12) Patent Application Publication
(10) Pub. No.: US 2007/0108544 A1
(43) Pub. Date: May 17, 2007

(54) Image sensor with a compound structure

(76) Inventors: Hsiu Wen Tu, Hsinchu Hsien (TW); Chen Pin Peng, Hsinchu Hsien (TW); Mon Nan Ho, Hsinchu Hsien (TW)

Correspondence Address: PRO-TECHTOR INTERNATIONAL SERVICES, 20775 NORADA CT., SARATOGA, CA, 95070, US

(21) Appl. No.: 11/282,392

(22) Filed: Nov. 17, 2005

(51) Int. Cl. H01L 31/0203

(52) U.S. Cl. 257/433

(57) ABSTRACT

An image sensor with a compound layer includes a substrate, a chip, wires, a compound layer, and a transparent layer. The substrate has an upper surface, which is formed with a central region and first electrodes arranged at the each side of the central region, and a lower surface, which is formed with second electrodes. The chip is mounted at the central region of the upper surface of the substrate. The chip has a sensor region and a plurality of bonding pads. The wires are electrically connected the bonding pads of the chip to the first electrodes of the substrate. The compound layer is located on the side of the chip and is covered on the wires. The transparent layer is arranged on the compound layer to cover the chip, so that the sensor region of the chip may be received optical signal through the transparent layer.

### BACKGROUND OF THE INVENTION

1. Field of the Invention

The invention relates an image sensor with a compound layer, and particular to a structure for packaging different size chip, the manufacturing cost may be decreased, and the size of the package may be decreased.

2. Description of the Related Art

Referring to FIG. 1, it is an image sensor structure includes a substrate 10, a frame layer 18, a photosensitive chip 26, a plurality of wires 28, and a transparent layer 34.

The substrate 10 has a first surface 12 on which plurality of first electrodes 15 are formed, and a second surface 14 on which plurality of second electrodes 16 are formed. The first electrodes 15 are corresponding to electrically connect to the second electrodes 16 by the conductive wires 17, which are located at the side of the substrate. The frame layer 18 has an upper surface 20 and a lower surface 22 adhered to the first surface 12 of the substrate 10 to form a cavity 24 together with the substrate 10. The photosensitive chip 26 is arranged within the chamber 24, and is mounted to the first surface 12 of the substrate 10. Each wire 28 has a first terminal 30 and a second terminal 32. The first terminals 30 are electrically connected to the photosensitive chip 26, and the second terminals 32 are electrically connected to the first electrodes 15 of the substrate 10. The transparent layer 34 is adhered to the upper surface 20 of the frame layer 18.

### SUMMARY OF THE INVENTION

An objective of the invention is to provide an image sensor with a compound structure, and capable of decreasing the manufacturing cast of the image sensor.

An objective of the invention is to provide an image sensor with a compound structure, and capable of decreasing the size of the structure.

To achieve the above-mentioned object, the invention includes an image sensor with a compound layer includes a substrate, a chip, wires, a compound layer, and a transparent layer. The substrate has an upper surface, which is formed with a central region and first electrodes arranged at the each side of the central region, and a lower surface, which is formed with second electrodes. The chip is mounted at the central region of the upper surface of the substrate, the chip has a sensor region and a plurality of bonding pads. The wires are electrically connected the bonding pads of the chip to the first electrodes of the substrate. The compound layer is located on the side of the chip and is covered on the wires. The transparent layer is arranged on the compound layer to cover the chip, so that the sensor region of the chip may be received optical signal through the transparent layer.

### BRIEF DESCRIPTION OF THE DRAWINGS

FIG. 1 is a schematic illustration showing a conventional image sensor structure.

FIG. 2 is a cross-sectional view illustration showing an image sensor with a compound structure.

FIG. 3 is a first schematic illustration showing an image sensor with a compound structure.

FIG. 4 is a second schematic illustration showing an image sensor with a compound structure.

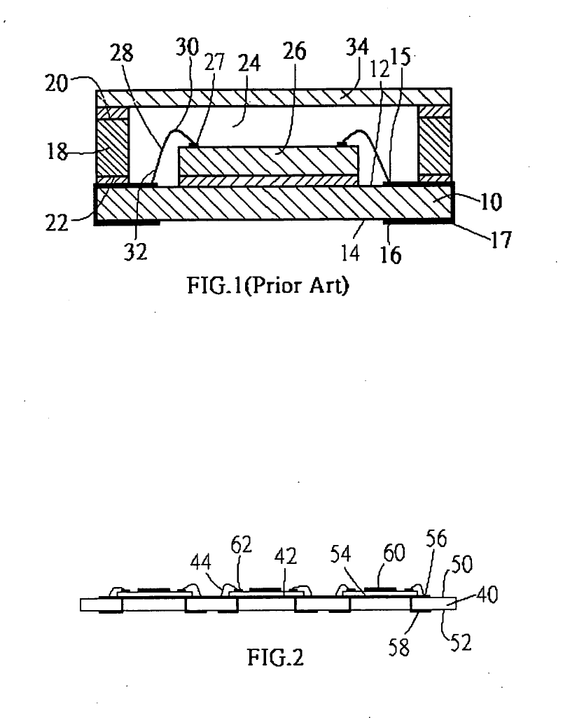

### DETAILED DESCRIPTION OF THE INVENTION

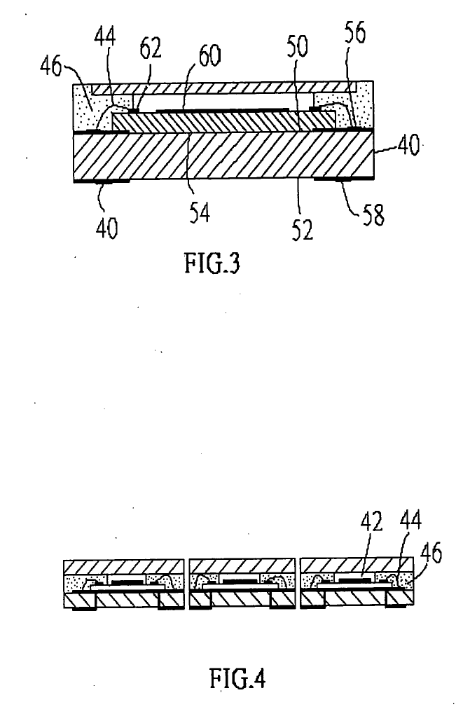

Please refer to FIG. 2 and FIG. 3, an image sensor package structure of the present invention includes substrate 40, a chip 42, wires 44, a compound layer 46, and a transparent layer 48.

The substrate 40 has an upper surface 5O, which is formed with a central region 54 and first electrodes 56 arranged at the each side of the central region 54, and a lower surface 52, which is formed with second electrodes 58 corresponding to electrically connect to the first electrodes 56.

The chip 42 is mounted at the central region 54 of the upper surface 50 of the substrate 40, the chip has a sensor region 60 and a plurality of bonding pads 62 are located at the side of the sensor region 54 of the chip 42.

The plurality of wires 44 are electrically connected the bonding pads 62 of the chip 42 to the first electrodes 56 of the substrate 40, so that the signal from the chip 42 is transmitted to the second electrodes 58 of the substrate 40 through the first electrodes 56.

Please refer to FIG.4, the compound layer 48 is formed of epoxy, is located on the side of the chip 40 and covered on the wires 44, so that the sensor region 60 of the chip 40 is exposed from the compound layer 48, then, to cut the compound layer 48 to form a single structure of image sensor.

The compound layer 48 is formed with a cavity 64 for locating the transparent layer 48.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. An image sensor with a compound structure, the structure comprising;
a substrate having an upper surface, which is formed with a central region and first electrodes arranged at the each side of the central region, and a lower surface, which is formed with second electrodes corresponding to electrically connect to the first electrodes;
a chip mounted at the central region of the upper surface of the substrate, the chip having a sensor region and a plurality of bonding pads located at the side of the sensor region of the chip;
a plurality of wires electrically connected the bonding pads of the chip to the first electrodes of the substrate, so that the signal from the chip transmitted to the second electrodes of the substrate through the first electrodes;
a compound layer located on the side of the chip and covered on the wires, so that the sensor region of the chip exposed from the compound layer ; and
a transparent layer arranged on the compound layer to cover the chip, so that the sensor region of the chip may received optical signal through the transparent layer.

2. The image sensor with a compound structure according to claim 1, wherein the compound layer is formed of epoxy.

3. The image sensor with a compound structure according to claim 1, wherein the compound layer is formed with a cavity for locating the transparent layer.
